(19) United States
(12) Patent Application Publication
(10) Pub. No.: US 2025/0192812 A1
(43) Pub. Date: Jun. 12, 2025

(54) PHASE CHARACTERISTIC MEASUREMENT DEVICE, SIGNAL GENERATOR AND SIGNAL ANALYZER HAVING SAME, AND PHASE CHARACTERISTIC MEASUREMENT METHOD

(71) Applicant: ANRITSU CORPORATION, Kanagawa (JP)

(72) Inventors: Hiroto FUJISAKI, Kanagawa (JP); Takashi MORI, Kanagawa (JP)

(21) Appl. No.: 18/953,742

(22) Filed: Nov. 20, 2024

(30) Foreign Application Priority Data
Dec. 12, 2023 (JP) 2023-209579

(51) Int. Cl. H04B 1/16; H03H 7/01; H03H 11/12

(52) U.S. Cl. CPC H04B 1/16; H03H 7/0161; H03H 7/1775; H03H 11/1291

(57) ABSTRACT

A phase characteristic measurement device includes a first detector 11 that receives and detects two patterns of three-tone signals of a first three-tone signal obtained by combining the three waves of angular frequencies ω₁, ω₂, ω₃ (wherein ω₂−ω₁=ω₃−ω₂=Δω) and a second three-tone signal obtained by changing a phase of one tone out of the first three-tone signal, a BPF 12 that allows only a beat component of an angular frequency difference Δω of adjacent waves of the three-tone signal from the signal output from the first detector to pass therethrough, a second detector 13 that detects power of the beat component that has passed through the BPF 12, a voltmeter 14 that measures the voltage of the signal output from the second detector, and a phase calculator 15 that calculates the phase based on the measured voltage value.

### TECHNICAL FIELD

The present invention relates to a phase characteristic measurement device, a signal generator and a signal analyzer having the same, and a phase characteristic measurement method.

### BACKGROUND ART

In order to improve a transmission speed in wireless communication, communication systems using wideband modulation signals in a millimeter wave band, a submillimeter wave band, or a terahertz wave band having a higher carrier frequency than in the related art are being considered. Hereinafter, the millimeter wave band, the submillimeter wave band, the terahertz wave band, and the like are collectively referred to as high-frequency bands, and signals in the high-frequency bands are collectively referred to as high-frequency signals.

In general, in the high frequency and wide bandwidth, the frequency characteristic of the phase of a frequency conversion unit (up-converter or down-converter) of a high-frequency band signal generator or a high-frequency band signal analyzer cannot be ignored, so that it is important to calibrate the phase characteristic of the frequency conversion unit. Furthermore, in a multi-level quadrature amplitude modulation system that has high spectral efficiency, even a small phase error can cause degradation of a transmission characteristic, so accurate calibration of the phase characteristic is required.

### RELATED ART DOCUMENT

### Patent Document

[Patent Document 1] Japanese Patent No. 5572590
[Patent Document 2] Japanese Patent No. 6839226

### DISCLOSURE OF THE INVENTION

### Problem that the Invention is to Solve

The related art disclosed in Patent Document 1 is a technology of measuring a frequency characteristic of a phase (simply referred to as a phase characteristic) by inputting two tone signals in a high-frequency band such as millimeter waves to an envelope detector (simply referred to as a detector), measuring a beat between the tones by the detector, and detecting a phase difference between the tones. However, in this method, it is necessary to obtain an initial phase of the beat between the tone signals. In order to obtain the initial phase, it is necessary to trigger an analog-to-digital converter (A/D converter) that acquires the time waveform of the detector output signal and synchronize the A/D converter with a tone signal generator. Such high-speed trigger operation requires expensive components, which is a problem.

In order to solve the above-described problems, there is a method of acquiring time waveforms of three tone signals in a high-frequency band, such as millimeter waves, and calculating a phase characteristic. By using the three tone signals, it is possible to measure the phase characteristic even in a case where the A/D converter is not triggered and the initial phase is unknown. Examples of the measurement using the three-tone signal include an electro-optical sampling method (for example, see Patent Document 2) and a method of down-converting a high-frequency signal such as millimeter waves. In particular, by using the electro-optical sampling method, the phase characteristic of a very high frequency can be accurately obtained. However, on the other hand, there is a problem that an optical system such as a femtosecond laser is required, making the device large in size. In the method of down-converting, a local signal in a high-frequency band, such as millimeter waves, is required, and there is a problem of making the device large in size.

An object of the present invention is to provide a phase characteristic measurement device that can perform phase measurement at a relatively low cost without increasing the scale of a device used for phase measurement, a signal generator and a signal analyzer having the same, and a phase characteristic measurement method.

### Means for Solving the Problem

In order to achieve the above object, a phase characteristic measurement device according to the present invention includes a first detector (11) that receives and detects a first three-tone signal obtained by combining three waves e₁, e₂, e₃ expressed by Expression (1) and a second three-tone signal obtained by combining three waves e′₁, e′₂, e′₃ expressed by Expression (2), a bandpass filter (12) that from the signal output from the first detector, passes a frequency component of the angular frequency difference Δω and blocks a frequency component twice the angular frequency difference Δω and a direct current component, a second detector (13) that detects the signal that has passed through the bandpass filter, a voltmeter (14) that measures a voltage of the signal output from the second detector, and a phase calculator (15) that calculates a phase φ₂″ expressed by Expression (3).

$${e}_{i} = cos ( {ω}_{i} t + {ϕ}_{i} ) , i = 1 , 2 , 3 \qquad ( 1 )$$

(where ωᵢ represents an angular frequency, φᵢ represents a phase, t represents time, and ω₂-ω₁=ω₃−ω₂=Δω.)

$${e}_{1}^{′} = cos ( {ω}_{1} t + {ϕ}_{1} ) \qquad ( 2 )$$

$${e}_{2}^{′} = sin ( {ω}_{2} t + {ϕ}_{2} )$$

$${e}_{3}^{′} = cos ( {ω}_{3} t + {ϕ}_{3} )$$

$${{ϕ}_{2}^{″} = \frac{{d}^{2} ϕ}{d {ω}^{2}} \vert}_{ω = {ω}_{2}} = \frac{{ϕ}_{3} - 2 {ϕ}_{2} + {ϕ}_{1}}{{Δω}^{2}} = \frac{2}{{Δω}^{2}} {tan}^{- 1} ( \pm \sqrt{\frac{{E}_{beat}^{′}}{{E}_{beat}}} ) \qquad ( 3 )$$

(where E_{beat} represents a value proportional to power of the signal that has passed through the bandpass filter, the value being obtained from a voltage value measured by the voltmeter when the first detector receives the first three-tone signal, and E′_{beat} represents a value proportional to power of the signal that has passed through the bandpass filter, the value being obtained from a voltage value measured by the voltmeter when the first detector receives the second three-tone signal.)

With this configuration, the power of the beat component of angular frequency Δω is measured by the second detector for two three-tone signal patterns, that is, the first three-tone signal represented by Expression (1) above and the second three-tone signal represented by Expression (2) above in which the phase of one tone is changed, thereby making it possible to calculate the phase relationship (second derivative) of the three tones represented by Expression (3) above. As a result, it is possible to provide a phase characteristic measurement device that can perform phase measurement at a relatively low cost without increasing the scale of the device, by using a voltmeter and a detector that do not require a high-speed trigger operation.

In order to achieve the above object, a phase characteristic measurement device according to the present invention includes a first detector (11) that receives and detects three-tone signals obtained by combining three waves e₁, e₂, e₃ expressed by Expression (4), a bandpass filter (12) that from the signal output from the first detector, passes a frequency component of the angular frequency difference Δω and blocks a frequency component twice the angular frequency difference Δω and a direct current component, a second detector (13) that detects the signal that has passed through the bandpass filter, a voltmeter (14) that measures a voltage of the signal output from the second detector, and a phase calculator (15) that calculates a phase φ₂″ expressed by Expression (5).

$${e}_{1} = {a}_{1} cos ( {ω}_{1} t + {ϕ}_{1} ) \qquad ( 4 )$$

$${e}_{2} ( ψ ) = {a}_{2} cos ( {ω}_{2} t + {ϕ}_{2} - ψ / 2 )$$

$${e}_{3} = {a}_{3} cos ( {ω}_{3} t + {ϕ}_{3} )$$

(where a₁, a₂, a₃ represent amplitudes, ω₁, ω₂, ω₃ represent angular frequencies, φ₁, φ₂, φ₃, ψ represent phases, t represents time, ψ=0, π/2, π, and ω₂−ω₁=ω₃−ω₂=Δω.)

$${ϕ}_{2}^{″} = \frac{1}{{Δω}^{2}} {tan}^{- 1} ( \frac{{E}_{beat} ( 0 ) - 2 {E}_{beat} ( π / 2 ) + {E}_{beat} ( π )}{{E}_{beat} ( 0 ) - {E}_{beat} ( π )} ) \qquad ( 5 )$$

(where E_{beat}(0) represents a value proportional to power of the signal that has passed through the bandpass filter, the value being obtained from a voltage value measured by the voltmeter when the first detector receives the three-tone signal when ψ=0, E_{beat}(π/2) represents a value proportional to power of the signal that has passed through the bandpass filter, the value being obtained from a voltage value measured by the voltmeter when the first detector receives the three-tone signal when ψ=π/2, and E_{beat}(π) represents a value proportional to power of the signal that has passed through the bandpass filter, the value being obtained from a voltage value measured by the voltmeter when the first detector receives the three-tone signal when ψ=π.)

With this configuration, by measuring the power of the beat component of the angular frequency Δω for the three-tone signal of three patterns (ψ=0, π/2, π) represented by Expression (4) using the second detector, the phase relationship (second derivative) of the three tones represented by Expression (5) can be calculated even in a case where the amplitudes a₁, a₂, a₃ of the three-tone signals are unknown and not equal to each other. As a result, it is possible to provide a phase characteristic measurement device that can perform phase measurement at a relatively low cost without increasing the scale of the device, by using a voltmeter and a detector that do not require a high-speed trigger operation. In addition, the measured phase is not affected by the offset generated during the E_{beat}(ψ) measurement.

In order to achieve the above object, a phase characteristic measurement device according to the present invention includes a first detector (11) that receives and detects three-tone signals obtained by combining three waves e₁, e₂, e₃ expressed by Expression (6), a bandpass filter (12) that from the signal output from the first detector, passes a frequency component of the angular frequency difference Δω and blocks a frequency component twice the angular frequency difference Δω and a direct current component, a second detector (13) that detects the signal that has passed through the bandpass filter, a voltmeter (14) that measures a voltage of the signal output from the second detector, and a phase calculator (15) that calculates a phase φ₂″ expressed by Expression (7).

$${e}_{1} = {a}_{1} cos ( {ω}_{1} t + {ϕ}_{1} ) \qquad ( 6 )$$

$${e}_{2} ( ψ ) = {a}_{2} cos ( {ω}_{2} t + {ϕ}_{2} - ψ / 2 )$$

$${e}_{3} = {a}_{3} cos ( {ω}_{3} t + {ϕ}_{3} )$$

(where a₁, a₂, a₃ represent amplitudes, ω₁, ω₂, ω₃ represent angular frequencies, φ₁, φ₂, φ₃, ψ represent phases, t represents time, ψ=0, π/2, π, and ω₂−ω₁=ω₃−ω₂=Δω.)

$${ϕ}_{2}^{″} = \frac{1}{{Δω}^{2}} atan 2 ( {E}_{beat} ( 0 ) - 2 {E}_{beat} ( π / 2 ) + {E}_{beat} ( π ) , {E}_{beat} ( 0 ) - {E}_{beat} ( π ) ) \qquad ( 7 )$$

(where E_{beat}(0) represents a value proportional to power of the signal that has passed through the bandpass filter, the value being obtained from a voltage value measured by the voltmeter when the first detector receives the three-tone signal when ψ=0, E_{beat}(π/2) represents a value proportional to power of the signal that has passed through the bandpass filter, the value being obtained from a voltage value measured by the voltmeter when the first detector receives the three-tone signal when ψ=π/2, and E_{beat}(π) represents a value proportional to power of the signal that has passed through the bandpass filter, the value being obtained from a voltage value measured by the voltmeter when the first detector receives the three-tone signal when ψ=π.)

With this configuration, by measuring the power of the beat component of the angular frequency Δω for the three-tone signal of three patterns (ψ=0, π/2, π) represented by Expression (6) using the second detector, the phase relationship (second derivative) of the three tones represented by Expression (11) can be calculated even in a case where the amplitudes a₁, a₂, a₃ of the three-tone signals are unknown and not equal to each other. In a case where the a tan 2 function is used in Expression (7), the phase measurement range is wider than in a case where the tan⁻¹ function in Expression (5) is used. As a result, it is possible to provide a phase characteristic measurement device that can perform phase measurement at a relatively low cost without increasing the scale of the device, by using a voltmeter and a detector that do not require a high-speed trigger operation. In addition, the measured phase is not affected by the offset generated during the E_{beat}(ψ) measurement.

A signal generator according to the present invention includes a high-frequency signal generation unit (2) that generates a high-frequency signal and three-tone signals, a coupler (3) that branches the signal output from the high-frequency signal generation unit and outputs one of the branched signals as an output signal, and the phase characteristic measurement device (1), which, when the high-frequency signal generation unit generates the three-tone signals, receives the other signal branched by the coupler as an input, and measures the phase φ₂″ from the input three-tone signals to measure a phase characteristic of the high-frequency signal generation unit, in which when the high-frequency signal generation unit generates the high-frequency signal, a phase characteristic of the high-frequency signal is corrected based on the phase characteristic of the high-frequency signal generation unit measured by the phase characteristic measurement device.

With this configuration, the same effects as those described above for the phase characteristic measurement device can be obtained, and the phase characteristic of the high-frequency signal generation unit can be corrected based on the phase characteristic of the high-frequency signal generation unit measured by the phase characteristic measurement device, making it possible to generate a high-frequency signal with good phase characteristic.

A signal analyzer according to the present invention includes a reference signal generation unit (20) that generates a reference signal and three-tone signals, a coupler (3) that branches the signal output from the reference signal generation unit, the phase characteristic measurement device (1) which, when the reference signal generation unit generates the three-tone signals, receives one signal branched by the coupler as an input, and measures the phase φ₂″ from the input three-tone signals to measure a phase characteristic of the reference signal generation unit, a switch (4) that selects either one of the other signal branched by the coupler or an input signal; and a high-frequency signal analysis unit (5) that analyzes the signal selected by the switch, in which a phase characteristic of the high-frequency signal analysis unit is calculated from a phase characteristic of the reference signal measured by the high-frequency signal analysis unit when the reference signal generation unit generates the reference signal and the other signal branched by the coupler is selected by the switch and the phase characteristic of the reference signal generation unit measured by the phase characteristic measurement device, a phase characteristic when the high-frequency signal analysis unit analyzes the input signal is corrected based on the calculated phase characteristic of the high-frequency signal analysis unit, and the input signal with the corrected phase characteristic is analyzed when the input signal is selected by the switch.

As described above, the phase characteristic of the reference signal generation unit is measured by the phase characteristic measurement device, and the signal having the known phase characteristic is input to the high-frequency signal analysis unit from the reference signal generation unit, so that the phase characteristic of the high-frequency signal analysis unit is measured, the phase characteristic of the high-frequency signal analysis unit is corrected based on the measured phase characteristic of the high-frequency signal analysis unit, and the signal analysis of the input signal is performed by the high-frequency signal analysis unit with the corrected phase characteristic. This provides the same effects as those described above for the phase characteristic measurement device, and also enables signal analysis corrected phase characteristic, thereby improving the quality of the analysis.

In order to achieve the above object, a phase characteristic measurement method according to the present invention includes a first three-tone signal generation step of generating a first three-tone signal obtained by combining three waves e₁, e₂, e₃ expressed by Expression (8), a first detection step of detecting the first three-tone signal, a first bandpass filter step of, from the signal obtained in the first detection step, passing a frequency component of the angular frequency difference Δω and blocking a frequency component twice the angular frequency difference Δω and a direct current component, a second detection step of detecting the signal passed in the first bandpass filter step, a first voltage measurement step of measuring a voltage of the signal obtained in the second detection step, a second three-tone signal generation step of generating a second three-tone signal obtained by combining three waves e′₁, e′₂, e′₃ expressed by Expression (9), a third detection step of detecting the second three-tone signal, a second bandpass filter step of, from the signal obtained in the third detection step, passing a frequency component of the angular frequency difference Δω between tones with adjacent frequencies of the second three-tone signal, and blocking a frequency component twice the angular frequency difference Δω and a direct current component, a fourth detection step of detecting the signal passed in the second bandpass filter step, a second voltage measurement step of measuring a voltage of the signal obtained in the fourth detection step, and a phase calculation step of calculating a phase φ₂″ expressed by Expression (10) from a voltage value measured in the first voltage measurement step and a voltage value measured in the second voltage measurement step.

$${e}_{i} = cos ( {ω}_{i} t + {ϕ}_{i} ) , i = 1 , 2 , 3 \qquad ( 8 )$$

(where ωᵢ represents an angular frequency, φᵢ represents a phase, t represents time, and ω₂−ω₁=ω₃−ω₂=Δω.)

$${e}_{1}^{′} = cos ( {ω}_{1} t + {ϕ}_{1} ) \qquad ( 9 )$$

$${e}_{2}^{′} = sin ( {ω}_{2} t + {ϕ}_{2} )$$

$${e}_{3}^{′} = cos ( {ω}_{3} t + {ϕ}_{3} )$$

$${{ϕ}_{2}^{″} = \frac{{d}^{2} ϕ}{d {ω}^{2}} \vert}_{ω = {ω}_{2}} = \frac{{ϕ}_{3} - 2 {ϕ}_{2} + {ϕ}_{1}}{Δ {ω}^{2}} = \frac{2}{Δ {ω}^{2}} {tan}^{- 1} ( \pm \sqrt{\frac{{E}_{beat}^{′}}{{E}_{beat}}} ) \qquad ( 10 )$$

(where E_{beat} represents a value proportional to power of the signal that has passed in the first bandpass filter step, the value being obtained from the voltage value measured in the first voltage measurement step, and E′_{beat} represents a value proportional to power of the signal that has passed in the second bandpass filter step, the value being obtained from the voltage value measured in the second voltage measurement step.)

With this configuration, the power of the beat component of angular frequency Δω is measured for two three-tone signal patterns, that is, the first three-tone signal represented by Expression (8) above and the second three-tone signal represented by Expression (9) above in which the phase of one tone is changed, thereby making it possible to calculate the phase relationship (second derivative) of the three tones represented by Expression (10) above. As a result, it is possible to provide a phase characteristic measurement method that can perform phase measurement at a relatively low cost without using large-scale device by using a voltmeter and a detector that do not require a high-speed trigger operation.

In order to achieve the above object, a phase characteristic measurement method according to the present invention includes a three-tone signal generation step of generating a three-tone signal obtained by combining three waves e₁, e₂, e₃ expressed by Expression (11), a first detection step of detecting the three-tone signal, a bandpass filter step of, from the signal obtained in the first detection step, passing a frequency component of the angular frequency difference Δω and blocking a frequency component twice the angular frequency difference Δω and a direct current component, a second detection step of detecting the signal passed in the bandpass filter step, a voltage measurement step of measuring a voltage of the signal obtained in the second detection step, and a phase calculation step of setting a phase ψ in Expression (11) to 0, π/2, and π, and calculating a phase φ₂″ expressed by Expression (12) from each voltage value measured by executing the three-tone signal generation step, the first detection step, the bandpass filter step, the second detection step, and the voltage measurement step, respectively.

$${e}_{1} = {a}_{1} cos ( {ω}_{1} t + {ϕ}_{1} ) \qquad ( 11 )$$

$${e}_{2} ( ψ ) = {a}_{2} cos ( {ω}_{2} t + {ϕ}_{2} - ψ / 2 )$$

$${e}_{3} = {a}_{3} cos ( {ω}_{3} t + {ϕ}_{3} )$$

(where a₁, a₂, a₃ represent amplitudes, ω₁, ω₂, ω₃ represent angular frequencies, φ₁, φ₂, φ₃, ψ represent phases, t represents time, ψ=0, π/2, π, and ω₂−ω₁=ω₃−ω₂=Δω.)

$${ϕ}_{2}^{″} = \frac{1}{Δ {ω}^{2}} {tan}^{- 1} ( \frac{{E}_{beat} ( 0 ) - 2 {E}_{beat} ( π / 2 ) + {E}_{beat} ( π )}{{E}_{beat} ( 0 ) - {E}_{beat} ( π )} ) \qquad ( 12 )$$

(where E_{beat}(0) represents a value proportional to power of the signal that has passed in the bandpass filter step, the value being obtained from the voltage value measured in the voltage measurement step when ψ=0, E_{beat}(π/2) represents a value proportional to power of the signal that has passed in the bandpass filter step, the value being obtained from the voltage value measured in the voltage measurement step when ψ=π/2, and E_{beat}(π) represents a value proportional to power of the signal that has passed in the bandpass filter step, the value being obtained from the voltage value measured in the voltage measurement step when ψ=π.)

With this configuration, by measuring the power of the beat component of the angular frequency Δω for the three-tone signal of three patterns (ψ=0, π/2, π) represented by Expression (11), the phase relationship (second derivative) of the three tones represented by Expression (12) can be calculated even in a case where the amplitudes a₁, a₂, a₃ of the three-tone signals are unknown and not equal to each other. As a result, it is possible to provide a phase characteristic measurement method that can perform phase measurement at a relatively low cost without using large-scale device by using a voltmeter and a detector that do not require a high-speed trigger operation. In addition, the measured phase is not affected by the offset generated during the E_{beat}(ψ) measurement.

In order to achieve the above object, a phase characteristic measurement method according to the present invention includes a three-tone signal generation step of generating a three-tone signal obtained by combining three waves e₁, e₂, e₃ expressed by Expression (13), a first detection step of detecting the three-tone signal, a bandpass filter step of, from the signal obtained in the first detection step, passing a frequency component of the angular frequency difference Δω and blocking a frequency component twice the angular frequency difference Δω and a direct current component, a second detection step of detecting the signal passed in the bandpass filter step, a voltage measurement step of measuring a voltage of the signal obtained in the second detection step, and a phase calculation step of setting a phase ψ in Expression (13) to 0, π/2, and π, and calculating a phase φ₂″ expressed by Expression (14) from each voltage value measured by executing the three-tone signal generation step, the first detection step, the bandpass filter step, the second detection step, and the voltage measurement step, respectively.

$${e}_{1} = {a}_{1} cos ( {ω}_{1} t + {ϕ}_{1} ) \qquad ( 13 )$$

$${e}_{2} ( ψ ) = {a}_{2} cos ( {ω}_{2} t + {ϕ}_{2} - ψ / 2 )$$

$${e}_{3} = {a}_{3} cos ( {ω}_{3} t + {ϕ}_{3} )$$

(where a₁, a₂, a₃ represent amplitudes, ω₁, ω₂, ω₃ represent angular frequencies, φ₁, φ₂, φ₃, ψ represent phases, t represents time, ψ=0, π/2, π, and ω₂−ω₁=ω₃−ω₂=Δω.)

$${ϕ}_{2}^{″} = \frac{1}{Δ {ω}^{2}} atan 2 ( {E}_{beat} ( 0 ) - 2 {E}_{beat} ( π / 2 ) + {E}_{beat} ( π ) , {E}_{beat} ( 0 ) - {E}_{beat} ( π ) ) \qquad ( 14 )$$

(where E_{beat}(0) represents a value proportional to power of the signal that has passed in the bandpass filter step, the value being obtained from the voltage value measured in the voltage measurement step when ψ=0, E_{beat}(π/2) represents a value proportional to power of the signal that has passed in the bandpass filter step, the value being obtained from the voltage value measured in the voltage measurement step when ψ=π/2, and E_{beat}(π) represents a value proportional to power of the signal that has passed in the bandpass filter step, the value being obtained from the voltage value measured in the voltage measurement step when ψ=π.)

With this configuration, by measuring the power of the beat component of the angular frequency Δω for the three-tone signal of three patterns (ψ=0, π/2, π) represented by Expression (13), the phase relationship (second derivative) of the three tones represented by Expression (14) can be calculated even in a case where the amplitudes a₁, a₂, a₃ of the three-tone signals are unknown and not equal to each other. In a case where the a tan 2 function is used in Expression (14), the phase measurement range is wider than in a case where the tan⁻¹ function in Expression (12) is used. As a result, it is possible to provide a phase characteristic measurement method that can perform phase measurement at a relatively low cost without using large-scale device by using a voltmeter and a detector that do not require a high-speed trigger operation. In addition, the measured phase is not affected by the offset generated during the E_{beat}(ψ) measurement.

A signal generation method according to the present invention includes a three-tone signal generation step of generating three-tone signals using a high-frequency signal generation unit, the phase characteristic measurement method for measuring a phase characteristic of the high-frequency signal generation unit by measuring the phase φ₂″ from the three-tone signals generated in the three-tone signal generation step, and a high-frequency signal generation step of generating a high-frequency signal using the high-frequency signal generation unit and outputting the high-frequency signal as an output signal, in which a phase characteristic of the high-frequency signal is corrected based on the phase characteristic of the high-frequency signal generation unit measured by the phase characteristic measurement method.

With this configuration, the same effects as those described above for the phase characteristic measurement method can be obtained, and the phase characteristic of the high-frequency signal can be corrected based on the phase characteristic of the high-frequency signal generation unit measured by the phase characteristic measurement method, making it possible to generate a high-frequency signal with good phase characteristic.

In order to achieve the above object, a signal analysis method according to the present invention includes a three-tone signal generation step of generating three-tone signals using a reference signal generation unit, the phase characteristic measurement for measuring phase characteristic of the reference signal generation unit by measuring the phase φ₂″ from the three-tone signals generated in the three-tone signal generation step, a reference signal generation step of generating a reference signal using the reference signal generation unit, a reference signal analysis step of measuring a phase characteristic of the reference signal using a high-frequency signal analysis unit, and a high-frequency signal analysis step of analyzing an input signal using the high-frequency signal analysis unit, in which a phase characteristic of the high-frequency signal analysis unit is calculated from the phase characteristic of the reference signal generation unit measured by the phase characteristic measurement method and the phase characteristic of the reference signal measured in the reference signal analysis step, a phase characteristic when the input signal is analyzed in the high-frequency signal analysis step is corrected based on the calculated phase characteristic of the high-frequency signal analysis unit, and the input signal with the corrected phase characteristic is analyzed.

As described above, the phase characteristic of the reference signal generation unit is measured by the phase characteristic measurement method, and the reference signal having the known phase characteristic is analyzed in the high-frequency signal analysis step, whereby the phase characteristic of the high-frequency signal analysis unit is measured, and the phase characteristic in a case of performing the signal analysis of the input signal is corrected based on the measured phase characteristic of the high-frequency signal analysis unit. This provides the same effects as those described above for the phase characteristic measurement method, and also enables signal analysis with corrected phase characteristic, thereby improving the quality of the analysis.

### Advantage of the Invention

According to the present invention, it is possible to provide a phase characteristic measurement device that can perform phase measurement at a relatively low cost without increasing the scale of a device used for phase measurement, a signal generator and a signal analyzer having the same, and a phase characteristic measurement method.

### BRIEF DESCRIPTION OF THE DRAWINGS

FIG. 1 is a diagram showing a configuration of a phase characteristic measurement system using a detector, according to an embodiment of the present invention.

FIG. 2 is a diagram showing a configuration of a phase characteristic measurement device (three-tone equal amplitude) according to the embodiment of the present invention.

FIG. 3 is a diagram showing a configuration of a phase characteristic measurement device (three-tone unequal amplitude) according to the embodiment of the present invention.

FIG. 4 is a diagram showing a schematic configuration of a signal generator provided with the phase characteristic measurement device according to the embodiment of the present invention.

FIG. 5 is a diagram showing a detailed configuration of the signal generator provided with the phase characteristic measurement to the device according embodiment of the present invention.

FIG. 6 is a diagram showing a schematic configuration of a signal analyzer provided with the phase characteristic measurement device according to the embodiment of the present invention.

FIG. 7 is a diagram showing a detailed configuration of the signal analyzer provided with the phase characteristic measurement device according to the embodiment of the present invention.

### BEST MODE FOR CARRYING OUT THE INVENTION

Hereinafter, embodiments of the present invention will be described with reference to the drawings.

First, the measurement principle of a phase characteristic measurement system using a detector used in the embodiment of the present invention will be described. FIG. 1 shows a schematic configuration of a phase characteristic measurement system 10 according to an embodiment of the present invention. First, a three-tone signal in which three waves (frequencies f₁, f₂, and f₃) in a high-frequency band are combined is input to the first detector 11. The frequencies of the respective tones of the three-tone signal are equally spaced (f₂−f₁=f₃−f₂). The first detector 11 performs square detection on the input three-tone signal and outputs a detection result having a frequency lower than the frequency of the three-tone signal. Therefore, the first detector 11 generates a DC component proportional to the average power of the three-tone signal and a beat between the tones. A frequency of a beat between the wave of the frequency f₁ and the wave of the frequency f₂ is f₂−f₁, a frequency of a beat between the wave of the frequency f₂ and the wave of the frequency f₃ is f₃−f₂, and a frequency of a beat between the wave of the frequency f₁ and the wave of the frequency f₃ is f₃−f₁. Therefore, from the first detector 11, the DC component, the frequency component of the frequency spacing Δf (=f₂−f₁=f₃−f₂) of the adjacent waves, and the frequency component of the frequency spacing 2Δf (=f₃−f₁) of the waves at both ends are output. The bandpass filter (BPF) 12 removes the DC component and the frequency component twice the tone spacing Δf (=f₂−f₁=f₃−f₂), and allows only the frequency component of the tone spacing to pass therethrough. That is, the beat components of the frequencies of f₂−f₁ and f₃−f₂ are extracted by the BPF 12. The beat component output from the BPF 12 is input to the second detector 13. The second detector 13 performs square detection on the input beat component and outputs a detection result having a frequency lower than the frequency of the beat component. Since the beat component input to the second detector 13 is a sinusoidal wave having a constant amplitude, a direct current voltage proportional to the power of the beat component is output from the second detector 13. That is, the power of the signal that is the sum of the two beat components extracted by the BPF 12 is detected by the second detector 13, and the magnitude of the detected power is measured by the voltmeter 14. The phase of the beat component output from the first detector 11 is changed according to the phase of the three-tone signal, and the two beat components of f₂−f₁ and f₃−f₂ interfere with each other because the frequencies thereof are equal to each other, so that the power of the beat component of the frequency Δf is changed according to the phase of the beat component. By changing the phase of any of the tones of the three-tone signal and measuring a change in power of the beat component of the frequency Δf at that time with the second detector 13 and the voltmeter 14, the phase relationship (second derivative) of the three tones can be calculated using the calculation expression described below. By step-sweeping the frequency of the three-tone signal, the phase characteristic in any frequency range can be obtained.

As the second detector 13, not only the detector that outputs a voltage proportional to the power of the input signal but also a detector that outputs a voltage proportional to the logarithm of the power of the input signal can be used. In a case where a logarithmic output detector is used, the output voltage of the detector is converted into the input power of the detector by the following Expression (15). Here, Pᵢₙ is the input power of the detector, Vₒᵤₜ is the output voltage of the detector, α is the sensitivity of the detector (unit: V/dB), and P_{interc} (logarithmic intercept) is the input power corresponding to the output voltage zero.

$${P}_{i n} = {P}_{interc} {10}^{\frac{{V}_{out}}{10 α}} \qquad ( 15 )$$

It should be noted that, in the calculation expression described later, a value proportional to the power of the signal that has passed through the BPF 12 may be used in order to calculate the ratio of the power of the beat components, and a value proportional to the power may be calculated without performing the multiplication of P_{interc} in the above expression.

### First Embodiment

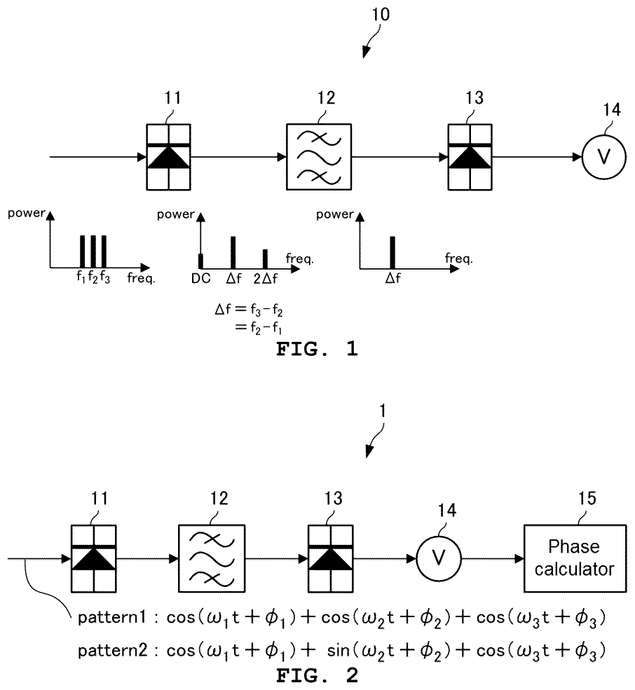

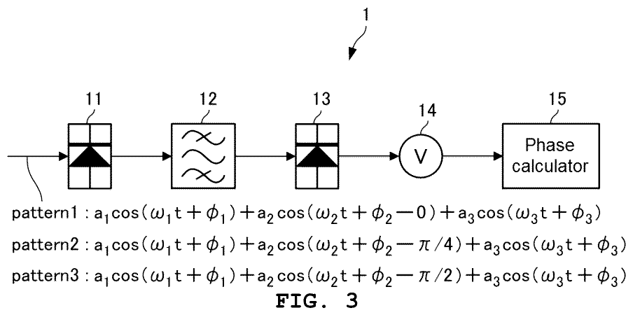

FIGS. 2 and 3 are diagrams showing a configuration of the phase characteristic measurement device according to a first embodiment of the present invention. As shown in FIGS. 2 and 3, the phase characteristic measurement device 1 according to the first embodiment includes a first detector 11, a BPF 12, a second detector 13, a voltmeter 14, and a phase calculator 15.

Specifically, the first detector 11 is configured to receive a three-tone signal in which three waves in the high-frequency band are combined, and to detect the power of the three-tone signal. The BPF 12 passes a frequency component of the angular frequency difference Δω (=ω₂−ω₁=ω₃−ω₂) between waves with adjacent frequencies of the three-tone signal and blocks a frequency component twice the angular frequency difference Δω and a direct current component, from the signal output from the first detector 11. The first detector 11 may be configured by using, for example, a detector including a diode, and may have a characteristic capable of detecting a three-tone signal obtained by combining three waves e₁, e₂, e₃ and outputting a beat component of an angular frequency Δω. The second detector 13 is configured to detect the power of the beat component that has passed through the BPF 12. The second detector 13 may be configured by a detector using a diode, for example, and have a characteristic of being able to detect the tone spacing angular frequency Δω of a three-tone signal. The voltmeter 14 is configured to measure the voltage of the signal output from the second detector 13. In addition, the voltmeter may be able to measure a voltage corresponding to the output of the second detector 13, and for example, any one of the anode or cathode of a diode detector is connected to one end of the voltmeter, and the other end is connected to a reference potential such as ground. In addition, in a case where the reference potential is stable, the other end of the voltmeter may not be the ground. The phase calculator 15 is configured to calculate a phase relationship and calculate a phase characteristic, as will be described later. The voltmeter 14 in the drawings may be an ammeter. In addition, the ammeter may be able to measure a current corresponding to the output of the second detector 13, and for example, any one of the anode or cathode of a diode detector is connected to one end of the ammeter. The other end of the ammeter may be connected to a reference potential, and a predetermined bias voltage may be applied to the diode. It should be noted that, in the calculation expression described later, in order to calculate the ratio of the power of the beat component, a value proportional to the power of the signal that has passed through the BPF 12 may be used, and in a case where the second detector 13 outputs a voltage or a current proportional to the input power, the measured voltage value or current value may be used as it is.

Here, a generation method of the three-tone signal input to the first detector 11 and a calculation method of the phase in the phase calculator 15 will be described. Two methods will be described: a simple method that can be used in a case where all three tones have the equal amplitude and a method that can be used even in a case where the amplitudes of the three tones are unknown and unequal.

Case where all Three Tones have Equal Amplitudes

First, a case where all of the three tones have the equal amplitude will be described with reference to FIG. 2. A three-tone signal is as follows.

$${e}_{i} = cos ( {ω}_{i} t + {ϕ}_{i} ) , i = 1 , 2 , 3 \qquad ( 16 )$$

Where t is the time, ωᵢ is the angular frequency of each tone, and φᵢ is the phase of each tone. The frequencies of the respective tones are equally spaced. That is, ωᵢ₊₁−ωᵢ=Δω, i=1, 2. In a case where the power of the three-tone signal (pattern 1) obtained by combining the three tones of the signals e₁, e₂, e₃ is detected by the first detector 11, a signal proportional to (e₁+e₂+e₃)² is obtained. The signal includes a direct current component, a component of the angular frequency Δω, and a component of the angular frequency 2Δω, as described above.

Only the beat component having the angular frequency Δω is extracted from this signal by the BPF 12. When the operator that extracts only the angular frequency Δω component with the BPF 12 is defined as BPF_{Δω}[ ], the beat component extracted by the BPF 12 is represented by Expression (17).

$${BPF}_{Δω} [ {( {e}_{1} + {e}_{2} + {e}_{3} )}^{2} ] = {BPF}_{Δω} [ 2 {e}_{1} + {e}_{2} + 2 {e}_{2} {e}_{3} ] = 2 cos ( \frac{{ϕ}_{3} - 2 {ϕ}_{2} + {ϕ}_{1}}{2} ) cos ( Δω t + \frac{{ϕ}_{3} - {ϕ}_{1}}{2} ) \qquad ( 17 )$$

Therefore, when the power E_{beat} of the beat component is detected by the second detector 13 and measured by the voltmeter 14,

$${E}_{beat} = 4 {cos}^{2} ( \frac{{ϕ}_{3} - 2 {ϕ}_{2} + {ϕ}_{1}}{2} ) \qquad ( 18 )$$

is satisfied.

Similarly, the second three-tone signal (pattern 2) obtained by combining the three waves e′₁, e′₂, and e′₃ represented by Expression (19) is detected by the first detector 11. ωᵢ, φᵢ, i=1, 2, 3 in Expression (19) are the same as ωᵢ, φᵢ, i=1, 2, 3 in Expression (16), respectively.

$${e}_{1}^{′} = cos ( {ω}_{1} t + {ϕ}_{1} ) \qquad ( 19 )$$

$${e}_{2}^{′} = sin ( {ω}_{2} t + {ϕ}_{2} )$$

$${e}_{3}^{′} = cos ( {ω}_{3} t + {ϕ}_{3} )$$

The beat component extracted by the BPF 12 at this time is represented by BPF_{Δω}[(e′₁+e′₂+e′₃)²], and in a case where the power E′_{beat} thereof is detected by the second detector 13 and measured by the voltmeter 14,

$${E}_{beat}^{′} = 4 {sin}^{2} ( \frac{{ϕ}_{3} - 2 {ϕ}_{2} + {ϕ}_{1}}{2} ) \qquad ( 20 )$$

is satisfied.

Therefore, the second derivative φ₂″ of the phase at the angular frequency ω₂ is represented by Expression (21), and is calculated by the phase calculator 15. The phase calculation method of Expression (21) is based on the division of E′_{beat}/E_{beat}, and since the result is not changed even in a case where E′_{beat} and E_{beat} are multiplied by a constant, E′_{beat} and E_{beat} may be values proportional to the power of the beat component extracted by the BPF 12.

$${{ϕ}_{2}^{″} = \frac{{d}^{2} ϕ}{d {ω}^{2}} \vert}_{ω = {ω}_{2}} = \frac{{ϕ}_{3} - 2 {ϕ}_{2} + {ϕ}_{1}}{Δ {ω}^{2}} = \frac{2}{Δ {ω}^{2}} {tan}^{- 1} ( \pm \sqrt{\frac{{E}_{beat}^{′}}{{E}_{beat}}} ) \qquad ( 21 )$$

By sweeping the frequency of the three-tone signal and finding the second derivative of the phase within the band to be measured using Expression (21) above, the frequency characteristic of the phase can be obtained by integrating the second derivative of the phase twice using Expression (22). The frequency the phase is calculated by, for example, the phase calculator 15. θ₀ and θ₀′ of Expression (22) are the initial phase and the initial phase gradient, and are arbitrary constants of integration.

$${θ}_{N} = {\sum }_{j = 1}^{N} ( {\sum }_{i = 1}^{J - 1} {ϕ}_{i}^{″} Δω + {θ}_{0}^{′} ) Δω + {θ}_{0} \qquad ( 22 )$$

Here, the sign of the argument in Expression (21) is undefined. That is, it is difficult to discriminate between positive and negative in the measurement in which φ₂″ is in the vicinity of zero. Therefore, it is desirable to add a known phase difference to the three-tone signal (pattern 1) and the second three-tone signal (pattern 2), and to perform measurement within the range of 0<φ₂″Δω²<π, for example, around φ₂″Δω²=π/2.

Case where Amplitude of Three Tones is Unknown

Next, a case where the amplitudes of the three tones are unknown and unequal will be described. In the above description, a case is considered in which the amplitudes of the tone signals are all equal to each other, but in reality, there is a frequency characteristic of the amplitude, and the amplitudes of tone signals are unknown and unequal. A three-tone signal is as follows.

$${e}_{1} = {a}_{1} cos ( {ω}_{1} t + {ϕ}_{1} ) \qquad ( 23 )$$

$${e}_{2} ( ψ ) = {a}_{2} cos ( {ω}_{2} t + {ϕ}_{2} - ψ / 2 )$$

$${e}_{3} = {a}_{3} cos ( {ω}_{3} t + {ϕ}_{3} )$$

Here, a₁, a₂, and a₃ are amplitudes of each tone, and only e₂ has a known phase −ψ/2. It is assumed that aᵢ, ωᵢ, φᵢ, i=1, 2, 3 do not change even in a case where ψ of Expression (23) is changed.

When the three-tone signal obtained by combining signals of three tones e₁, e₂ (ψ), and e₃ is detected by the first detector 11 and the component of the angular frequency Δω is extracted by the BPF 12, the BPF_{Δω}[(e₁+e₂(ψ)+e₃)²], and the power thereof is defined as E_{beat}(ψ). In a case where the output signal of the BPF 12 is detected by the second detector 13 and the output voltage of the second detector 13 is measured by the voltmeter 14, E_{beat}(ψ) is obtained. In particular, in a case of calculating the power with a focus on the case where ψ=0, π/2, π,

$$\begin{matrix}{E}_{beat} ( 0 ) = 2 {a}_{1} {a}_{2}^{2} {a}_{3} cos ( {ϕ}_{3} - 2 {ϕ}_{2} + {ϕ}_{1} ) + {a}_{1}^{2} {a}_{2}^{2} + {a}_{2}^{2} {a}_{3}^{2} \\ {E}_{beat} ( π / 2 ) = - 2 {a}_{1} {a}_{2}^{2} {a}_{3} sin ( {ϕ}_{3} - 2 {ϕ}_{2} + {ϕ}_{1} ) + {a}_{1}^{2} {a}_{2}^{2} + {a}_{2}^{2} {a}_{3}^{2} \\ {E}_{beat} ( π ) = - 2 {a}_{1} {a}_{2}^{2} {a}_{3} cos ( {ϕ}_{3} - 2 {ϕ}_{2} + {ϕ}_{1} ) + {a}_{1}^{2} {a}_{2}^{2} + {a}_{2}^{2} {a}_{3}^{2}\end{matrix} \qquad ( 24 )$$

is satisfied.

From this result, the second derivative of the phase is as follows:

$${ϕ}_{2}^{″} = \frac{1}{Δ {ω}^{2}} {tan}^{- 1} ( \frac{{E}_{beat} ( 0 ) - 2 {E}_{beat} ( π / 2 ) + {E}_{beat} ( π )}{{E}_{beat} ( 0 ) - {E}_{beat} ( π )} ) \qquad ( 25 )$$

is satisfied. Since the value range of the tan⁻¹ function is −π/2 to +π/2, it is desirable to perform measurement within the range of −π/2<φ₂″Δω²<π/2 for example, around φ₂″Δω²=0.

In addition, in a case where the a tan 2 function is used,

$${ϕ}_{2}^{″} = \frac{1}{Δ {ω}^{2}} a tan 2 ( {E}_{beat} ( 0 ) - 2 {E}_{beat} ( π / 2 ) + {E}_{beat} ( π ) , {E}_{beat} ( 0 ) - {E}_{beat} ( π ) ) \qquad ( 26 )$$

phase measurement is possible within the range of φ₂″Δω² of 2π. Since the value range of the a tan 2 function is from −π to +π, it is desirable to perform measurement within the range of −π<φ₂″Δω²<π, for example, around φ₂″Δω²=0. The phase calculator 15 performs the calculation of Expression (25) or Expression (26), and the second derivative φ₂″ of the phase at the angular frequency ω₂ is obtained. The phase calculation method of Expression (25) and Expression (26) also has an effect of removing the DC offset during the E_{beat}(ψ) measurement, because even in a case where the direct current offset E_{DC} is added during the E_{beat}(ψ) measurement, (E_{beat}(0)+E_{DC})−2(E_{beat}(π/2)+E_{DC})+(E_{beat}(π)+E_{DC})=E_{beat}(0)−2E_{beat}(π/2)+E_{beat}(π) and (E_{beat}(0)+E_{DC})−(E_{beat}(π)+E_{DC})=E_{beat}(0)−E_{beat}(π) are obtained and all the direct current offsets E_{DC} are canceled out. In addition, since the phase calculation method of Expression (25) and Expression (26) are based on the ratio of E_{beat}(0)−2E_{beat}(π/2)+E_{beat}(π) and E_{beat}(0)−E_{beat}(π), and the result is not changed even in a case where E_{beat}(ψ) is multiplied by a constant, E_{beat}(ψ) may be a value proportional to the power of the beat component extracted by the BPF 12. Similarly to the above, the frequency characteristic of the phase can be calculated by sweeping the frequency of the three-tone signal and integrating the second derivative of the phase twice using Expression (22).

### Definition of a tan 2 Function

a tan 2 (y, x) is a function that returns the argument of a point (x, y) in a rectangular coordinate system. The possible value range is −π<a tan 2≤π.

FIG. 3 shows a configuration example of the phase characteristic measurement device 1 in a case where the amplitudes of the three tones are unknown. As shown in FIG. 3, the first detector 11 receives a three-tone signal obtained by combining three waves represented by Expression (23) in three patterns (ψ=0, π/2, π), and detects the power of each of the three-tone signals. The BPF 12 is configured to pass the frequency component of the angular frequency difference Δω (=ω₂−ω₁=ω₃−ω₂) of the adjacent waves of the three-tone signal and to block the frequency component twice the angular frequency difference Δω and the direct current component, from the signal output from the first detector 11. The second detector 13 and the voltmeter 14 are configured to measure the power E_{beat}(ψ) of the beat component that has passed through the BPF 12. The phase calculator 15 is configured to calculate the phase relationship (second derivative) indicated by Expression (25) or Expression (26) to calculate the phase characteristic.

The phase characteristic measurement technique presented in the present specification can be applied not only to devices that measure the phase characteristic but also to signal generators (SG) or signal analyzers (SA) that incorporate the devices. As a result, it is expected that the quality of modulation and demodulation of the wideband signal is improved.

### Second Embodiment

Next, a signal generator provided with the phase characteristic measurement device will be described.

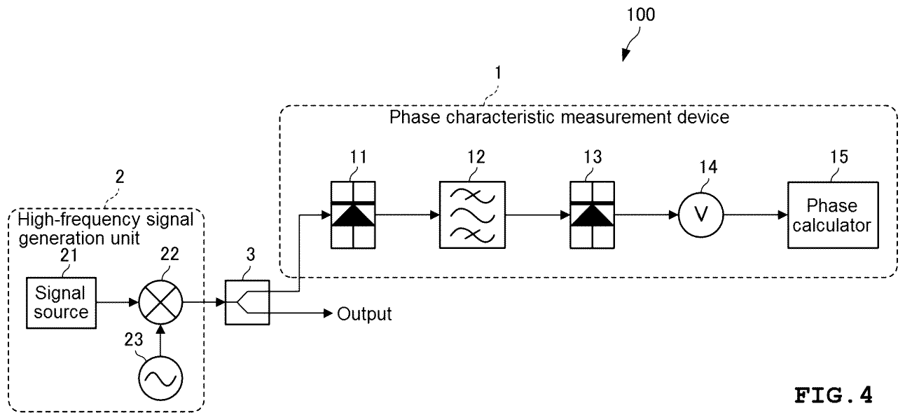

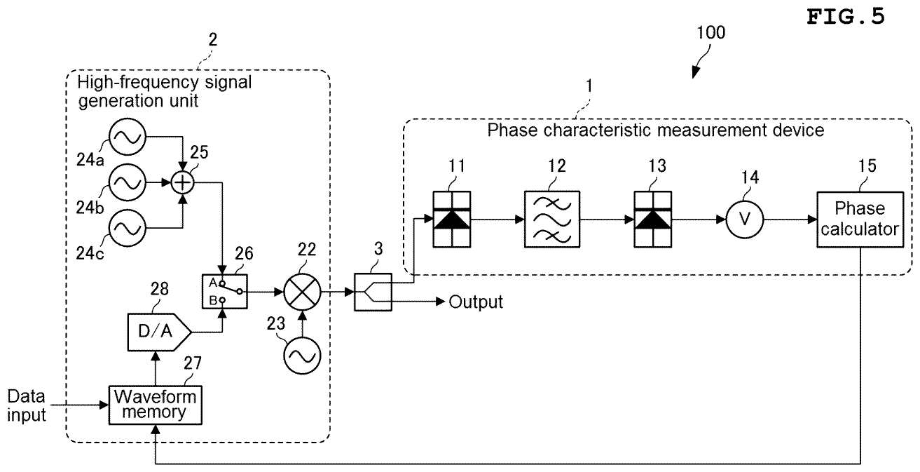

FIG. 4 shows a schematic configuration of a signal generator 100 provided with the phase characteristic measurement device and FIG. 5 shows a detailed configuration. As shown in FIGS. 4 and 5, the signal generator 100 includes the phase characteristic measurement device 1, a high-frequency signal generation unit 2, and a coupler 3. The phase characteristic of the high-frequency signal generation unit 2 is corrected based on the phase characteristic of the high-frequency signal generation unit 2 measured by the phase characteristic measurement device 1.

Specifically, the high-frequency signal generation unit 2 includes a signal source 21, a frequency conversion unit 22, and a local oscillator unit 23, and uses the local oscillator unit 23 that generates the CW local signal and the frequency conversion unit 22 such as a mixer to frequency-convert (up-convert) the signal generated by the signal source 21 into a signal of a high-frequency band frequency and output the high-frequency signal. The coupler 3 branches the high-frequency signal output from the high-frequency signal generation unit 2, and outputs one signal as an output signal and outputs the other signal to the phase characteristic measurement device 1. The phase characteristic measurement device 1 receives the high-frequency signal branched by the coupler 3 and measures the phase characteristic of the input signal.

Specifically, as shown in FIG. 5, the high-frequency signal generation unit 2 includes an intermediate frequency signal generators 24a to 24c, an adder 25, a switch 26, a frequency conversion unit 22, a local oscillator unit 23, a waveform memory 27, and a digital-to-analog converter (D/A converter) 28.

In a case where the switch 26 is set to the contact A, the high-frequency signal generation unit 2 adds (combines) the intermediate frequency signals of the sinusoidal waves generated by the intermediate frequency signal generators 24a to 24c by the adder 25, and the frequency conversion unit 22 performs frequency conversion (up-conversion) to output the three-tone signal of the high-frequency band. A part of the three-tone signal output from the high-frequency signal generation unit 2 is sent to the phase characteristic measurement device 1 via the coupler 3, and the phase characteristic of the high-frequency signal generation unit 2 is measured.

A signal to be generated by the high-frequency signal generation unit 2 is calculated in advance by digital operation and is stored in the waveform memory 27. In a case where the switch is set to the contact B, the data of the waveform memory 27 is input to the D/A converter 28 to be converted into an analog signal, and the analog signal is subjected to frequency conversion (up-conversion) by the frequency conversion unit 22 and output as a high-frequency signal. In this case, by applying the inverse characteristic of the phase characteristic of the high-frequency signal generation unit 2, which is measured in advance, to the signal stored in the waveform memory 27 of the high-frequency signal generation unit 2, a high-frequency signal with a corrected phase characteristic is output, and the modulation quality of the high-frequency signal generation unit 2 can be improved. In FIG. 5, the inverse characteristic of the phase characteristic is applied to the signal stored in the waveform memory 27, but it is also possible to correct the phase characteristic by applying a filter having the inverse characteristic of the phase characteristic to the digital signal output from the waveform memory 27.

Since the signal generator 100 can output a signal with the corrected phase characteristic, the signal can be used as a reference signal for correcting the phase characteristic of an external high-frequency signal receiving device or the like. In this case, the switch 26 may be set to the contact A to output the three-tone signal, or may be set to the contact B to output the wideband signal (for example, the multi-tone signal of three or more waves). In a case where the switch 26 is set to the contact A, the inverse characteristic of the phase characteristic of the high-frequency signal generation unit 2 measured by the phase characteristic measurement device 1 may be set to the initial phase of the intermediate frequency signal generator 24a to 24c. In a case where the switch 26 is set to contact B, by applying the inverse characteristic of the phase characteristic of the high-frequency signal generation unit 2 measured by the phase characteristic measurement device 1 to the signal stored in the waveform memory 27, a wideband signal with corrected phase characteristic may be output. The coupler 3 may be, for example, a switch. In a case where the coupler 3 is replaced with the second switch, when the second switch is set to send a signal to the phase characteristic measurement device 1, a calibration operation is performed, whereas in a case where the second switch is set to an output side, the switch 26 can be set to the contact B and an operation for generating a signal can be performed.

### Third Embodiment

Next, a signal analyzer including a phase characteristic measurement device will be described.

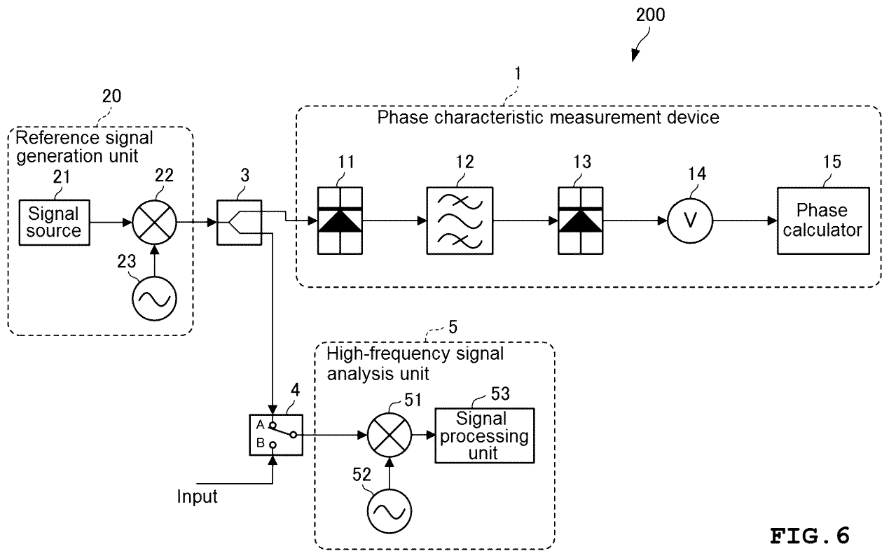

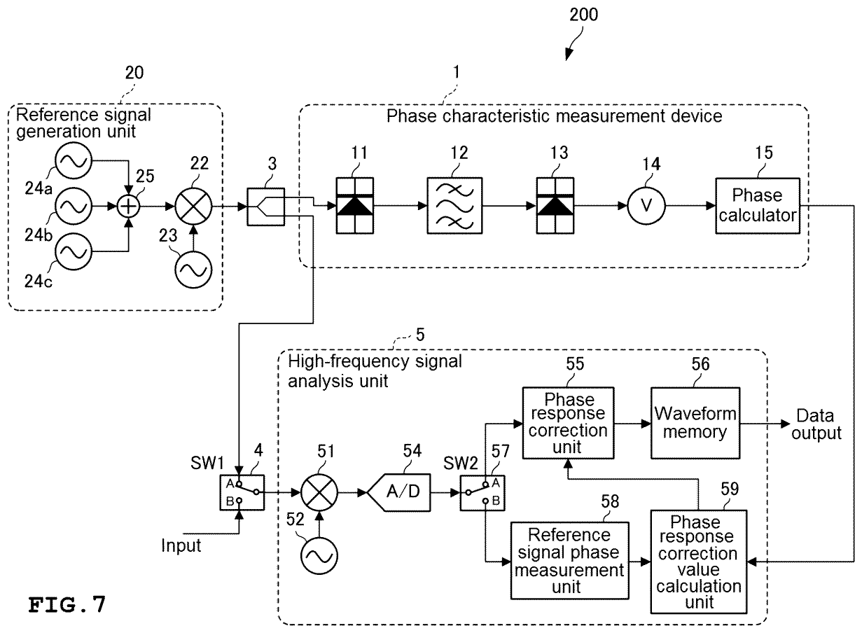

FIG. 6 shows a schematic configuration of a signal analyzer 200 provided with the phase characteristic measurement device 1, and FIG. 7 shows a detailed configuration. As shown in FIGS. 6 and 7, the signal analyzer 200 includes the phase characteristic measurement device 1, a reference signal generation unit 20, a coupler 3, a switch 4, and a high-frequency signal analysis unit 5. The phase characteristic of the reference signal generation unit 20 is measured by the phase characteristic measurement device 1, the reference signal having a known phase characteristic is input to the high-frequency signal analysis unit 5 from the reference signal generation unit 20, and the phase characteristic of the high-frequency signal analysis unit 5 is measured, and the phase characteristic of the high-frequency signal analysis unit 5 is corrected based on the measured phase characteristic of the high-frequency signal analysis unit 5. Then, the high-frequency signal analysis unit 5 with the corrected phase characteristic performs the signal analysis of the input signal.

Specifically, the reference signal generation unit 20 includes a signal source 21, a frequency conversion unit 22, and a local oscillator unit 23, and uses the local oscillator unit 23 that generates the CW local signal and the frequency conversion unit 22 such as a mixer to frequency-convert (up-convert) the signal generated by the signal source 21 into a signal of a high-frequency band frequency and output the reference signal. The coupler 3 branches the reference signal output from the reference signal generation unit 20 and outputs one signal to the phase characteristic measurement device 1, and the switch 4 sends the other signal branched by the coupler 3 to the high-frequency signal analysis unit 5. The phase characteristic measurement device 1 receives the reference signal branched by the coupler 3 and measures the phase characteristic of the input signal. The switch 4 selects either one of the other signal of the reference signal branched by the coupler 3 or the input signal. The high-frequency signal analysis unit 5 includes a frequency conversion unit 51, a local oscillator unit 52, and a signal processing unit 53, and performs signal analysis by the signal processing unit 53 by frequency-converting (down-converting) the signal selected by the switch 4 by the frequency conversion unit 51 and the local oscillator unit 52.

Specifically, as shown in FIG. 7, the reference signal includes the intermediate frequency generation unit 20 signal generators 24a to 24c, an adder 25, a frequency conversion unit 22, and a local oscillator unit 23. The high-frequency signal analysis unit 5 includes a frequency conversion unit 51, a local oscillator unit 52, an A/D converter 54, a phase response correction unit 55, a waveform memory 56, a second switch 57, a reference signal phase measurement unit 58, and a phase response correction value calculation unit 59.

First, the phase characteristic of the reference signal generation unit 20 is measured by the phase characteristic measurement device 1. Specifically, the reference signal generation unit 20 adds (combines) the intermediate frequency signals of the sinusoidal waves generated by the intermediate frequency signal generators 24a to 24c by the adder 25, and the frequency conversion unit 22 performs frequency conversion (up-conversion) to output the three-tone signal of the high-frequency band. A part of the three-tone signal output from the reference signal generation unit 20 is sent to the phase characteristic measurement device 1 via the coupler 3, and the phase characteristic of the reference signal generation unit 20 is measured.

Next, the switch 4 is set to the contact A, and the second switch 57 is set to the contact B. The phase characteristic of the high-frequency signal analysis unit 5 is measured by inputting a wideband signal having a known phase characteristic from the reference signal generation unit 20 to the high-frequency signal analysis unit 5 as the reference signal (in FIG. 7, the wideband signal is shown as a three-tone signal, but may be, for example, a multi-tone signal of four or more waves). Specifically, the reference signal sent from the reference signal generation unit 20 via the switch 4 is frequency-converted (down-converted) by the frequency conversion unit 51 and the local oscillator unit 52 in the high-frequency signal analysis unit 5, is converted into a digital signal by the A/D converter 54, and is sent to the reference signal phase measurement unit 58 via the second switch 57, and the phase characteristic of the reference signal is measured by the reference signal phase measurement unit 58. In FIG. 7, the reference signal is a three-tone signal, and the phase characteristic of the reference signal can be obtained by calculating the second derivative of the phase of the three-tone signal which has been frequency-converted and converted into a digital signal, sweeping the frequency of the three-tone signal, and integrating the second derivative of the phase twice. When the reference signal is a multi-tone signal having four or more waves, the second derivatives of the phase at a plurality of frequencies can be obtained at once, so that the phase characteristic of the reference signal can be obtained with a small number of frequency sweep points. The phase response correction value calculation unit 59 calculates the phase characteristic of the high-frequency signal analysis unit 5 from the phase characteristic of the reference signal measured by the reference signal phase measurement unit 58 and the phase characteristic of the reference signal generation unit 20 measured by the phase characteristic measurement device 1. That is, the phase characteristic of the high-frequency signal analysis unit 5 is obtained by subtracting the phase characteristic of the reference signal generation unit 20 measured by the phase characteristic measurement device 1 from the phase characteristic of the reference signal measured by the reference signal phase measurement unit 58. Here, the phase characteristic of the high-frequency signal analysis unit 5 is calculated from the phase characteristic of the reference signal measured by the reference signal phase measurement unit 58 and the phase characteristic of the reference signal generation unit 20 measured by the phase characteristic measurement device 1, but the phase of the reference signal generated by the reference signal generation unit 20 may be corrected by setting the inverse characteristic of the phase characteristic of the reference signal generation unit 20 measured by the phase characteristic measurement device 1 to the initial phase of the intermediate frequency signal generators 24a to 24c. In this case, since the reference signal with the corrected phase characteristic is input to the high-frequency signal analysis unit 5, the phase characteristic of the reference signal measured by the reference signal phase measurement unit 58 is the phase characteristic of the high-frequency signal analysis unit 5.

In a case where the switch 4 is set to the contact B and the second switch 57 is set to the contact A, the input signal is frequency-converted (down-converted) by the frequency conversion unit 51 and the local oscillator unit 52, is converted into the digital signal by the A/D converter 54, and the phase characteristic of the high-frequency signal analysis unit 5 is corrected by the phase response correction unit 55, is stored in the waveform memory 56 and output as the analysis data. That is, the signal analysis with the corrected phase characteristic of the high-frequency signal analysis unit 5 is performed, by applying the digital filter having the inverse characteristic of the phase characteristic of the high-frequency signal analysis unit 5 calculated by the phase response correction value calculation unit 59 to the digital signal output from the A/D converter 54 in the phase response correction unit 55, and the analysis quality (demodulation quality) can be improved.

In FIG. 7, the phase characteristic is corrected by applying a digital filter having the inverse characteristic of the phase characteristic of the high-frequency signal analysis unit 5 to the digital signal output from the A/D converter 54, but the phase characteristic may be corrected by once storing the digital signal output from the A/D converter 54 in the waveform memory 56 and applying the inverse characteristic of the phase characteristic to the waveform data in the waveform memory 56 by an offline process. In addition, the coupler 3 in the drawings may be, for example, a switch, and the switch 4 may be, for example, a coupler.

### INDUSTRIAL APPLICABILITY

As described above, the present invention has an effect of performing phase measurement at a relatively low cost without increasing the scale of a device used for phase measurement by using a voltmeter and a detector that do not require a high-speed trigger operation, and is useful for a phase characteristic measurement device, a signal generator and a signal analyzer having the same, and a phase characteristic measurement method.

### DESCRIPTION OF REFERENCE NUMERALS AND SIGNS

1: phase characteristic measurement device
10: phase characteristic measurement system
11: first detector
12: bandpass filter (BPF)
13: second detector
14: voltmeter
15: phase calculator
2: high-frequency signal generation unit
20: reference signal generation unit
21: signal source
22: frequency conversion unit
23: local oscillator unit
24a, 24b, 24c: intermediate frequency signal generator
25: adder
26: switch
27: waveform memory
28: D/A converter
3: coupler
4: switch
5: high-frequency signal analysis unit
51: frequency conversion unit
52: local oscillator unit
53: signal processing unit
54: A/D converter
55: phase response correction unit
56: waveform memory
57: second switch
58: reference signal phase measurement unit
59: phase response correction value calculation unit
100: signal generator
200: signal analyzer

What is claimed is:

1. A phase characteristic measurement device comprising:
a first detector that receives and detects a first three-tone signal obtained by combining three waves e₁, e₂, e₃ expressed by Expression (1) and a second three-tone signal obtained by combining three waves e′, e′₂, e′₃ expressed by Expression (2);
a bandpass filter that, from the signal output from the first detector, passes a frequency component of the angular frequency difference Δω and blocks a frequency component twice the angular frequency difference Δω and a direct current component;
a second detector that detects the signal that has passed through the bandpass filter;
a voltmeter that measures a voltage of the signal output from the second detector; and
a phase calculator that calculates a phase φ₂″ expressed by Expression (3),
$${e}_{i} = cos ( {ω}_{i} t + {ϕ}_{i} ) , i = 1 , 2 , 3 \qquad ( 1 )$$
(where ωᵢ represents an angular frequency, φᵢ represents a phase, t represents time, and ω₂−ω₁=ω₃−ω₂=Δω)
$$\begin{matrix}{e}_{1}^{′} = cos ( {ω}_{1} t + {ϕ}_{1} ) \\ {e}_{2}^{′} = sin ( {ω}_{2} t + {ϕ}_{2} ) \\ {e}_{3}^{′} = cos ( {ω}_{3} t + {ϕ}_{3} )\end{matrix} \qquad ( 2 )$$
$$\begin{matrix}{ϕ}_{2}^{″} = \frac{{d}^{2} ϕ}{d {ω}^{2}} {\vert}_{ω = {ω}_{2}} = \frac{{ϕ}_{3} - 2 {ϕ}_{2} + {ϕ}_{1}}{Δ {ω}^{2}} \\ = \frac{2}{Δ {ω}^{2}} {tan}^{- 1} ( \pm \sqrt{\frac{{E}_{beat}^{′}}{{E}_{beat}}} )\end{matrix} \qquad ( 3 )$$
(where E_{beat} represents a value proportional to power of the signal that has passed through the bandpass filter, the value being obtained from a voltage value measured by the voltmeter when the first detector receives the first three-tone signal, and E′_{beat} represents a value proportional to power of the signal that has passed through the bandpass filter, the value being obtained from a voltage value measured by the voltmeter when the first detector receives the second three-tone signal).

2. A phase characteristic measurement device comprising:
a first detector that receives and detects three-tone signals obtained by combining three waves e₁, e₂, e₃ expressed by Expression (4);
a bandpass filter that, from the signal output from the first detector, passes a frequency component of the angular frequency difference Δω and blocks a frequency component twice the angular frequency difference Δω and a direct current component;
a second detector that detects the signal that has passed through the bandpass filter;
a voltmeter that measures a voltage of the signal output from the second detector; and
a phase calculator that calculates a phase φ₂″ expressed by Expression (5),
$$\begin{matrix}{e}_{1} = {a}_{1} cos ( {ω}_{1} t + {ϕ}_{1} ) \\ {e}_{2} ( ψ ) = {a}_{2} cos ( {ω}_{2} t + {ϕ}_{2} - ψ / 2 ) \\ {e}_{3} = {a}_{3} cos ( {ω}_{3} t + {ϕ}_{3} )\end{matrix} \qquad ( 4 )$$
(where a₁, a₂, a₃ represent amplitudes, ω₁, ω₂, ω₃ represent angular frequencies, φ₁, φ₂, φ₃, ψ represent phases, t represents time, ψ=0, π/2, π, and ω₂−ω₁=ω₃−ω₂=Δω)
$${ϕ}_{2}^{″} = \frac{1}{Δ {ω}^{2}} {tan}^{- 1} ( \frac{{E}_{beat} ( 0 ) - 2 {E}_{beat} ( π / 2 ) + {E}_{beat} ( π )}{{E}_{beat} ( 0 ) - {E}_{beat} ( π )} ) \qquad ( 5 )$$
(where E_{beat}(0) represents a value proportional to power of the signal that has passed through the bandpass filter, the value being obtained from a voltage value measured by the voltmeter when the first detector receives the three-tone signal when ψ=0, E_{beat}(π/2) represents a value proportional to power of the signal that has passed through the bandpass filter, the value being obtained from a voltage value measured by the voltmeter when the first detector receives the three-tone signal when ψ=π/2, and E_{beat}(π) represents a value proportional to power of the signal that has passed through the bandpass filter, the value being obtained from a voltage value measured by the voltmeter when the first detector receives the three-tone signal when ψ=π).

3. A phase characteristic measurement device comprising:
a first detector that receives and detects three-tone signals obtained by combining three waves e₁, e₂, e₃ expressed by Expression (6);
a bandpass filter that, from the signal output from the first detector, passes a frequency component of the angular frequency difference Δω and blocks a frequency component twice the angular frequency difference Δω and a direct current component;
a second detector that detects the signal that has passed through the bandpass filter;
a voltmeter that measures a voltage of the signal output from the second detector; and
a phase calculator that calculates a phase φ₂″ expressed by Expression (7),
$$\begin{matrix}{e}_{1} = {a}_{1} cos ( {ω}_{1} t + {ϕ}_{1} ) \\ {e}_{2} ( ψ ) = {a}_{2} cos ( {ω}_{2} t + {ϕ}_{2} - ψ / 2 ) \\ {e}_{3} = {a}_{3} cos ( {ω}_{3} t + {ϕ}_{3} )\end{matrix} \qquad ( 6 )$$
(where a₁, a₂, a₃ represent amplitudes, ω₁, ω₂, ω₃ represent angular frequencies, φ₁, φ₂, φ₃, ψ represent phases, t represents time, ψ=0, π/2, π, and ω₂−ω₁=ω₃−ω₂=Δω)
$${ϕ}_{2}^{″} = \frac{1}{Δ {ω}^{2}} a tan 2 ( {E}_{beat} ( 0 ) - 2 {E}_{beat} ( π / 2 ) + {E}_{beat} ( π ) , {E}_{beat} ( 0 ) - {E}_{beat} ( π ) ) \qquad ( 7 )$$
(where E_{beat}(0) represents a value proportional to power of the signal that has passed through the bandpass filter, the value being obtained from a voltage value measured by the voltmeter when the first detector receives the three-tone signal when ψ=0, E_{beat}(π/2) represents a value proportional to power of the signal that has passed through the bandpass filter, the value being obtained from a voltage value measured by the voltmeter when the first detector receives the three-tone signal when ψ=π/2, and E_{beat}(π) represents a value proportional to power of the signal that has passed through the bandpass filter, the value being obtained from a voltage value measured by the voltmeter when the first detector receives the three-tone signal when ψ=π).

4. A signal generator comprising:
a high-frequency signal generation unit that generates a high-frequency signal and three-tone signals;
a coupler that branches the signal output from the high-frequency signal generation unit and outputs one of the branched signals as an output signal; and
the phase characteristic measurement device according to claim 1, which, when the high-frequency signal generation unit generates the three-tone signals, receives the other signal branched by the coupler as an input, and measures the phase φ₂″ from the input three-tone signals to measure a phase characteristic of the high-frequency signal generation unit, wherein
when the high-frequency signal generation unit generates the high-frequency signal, a phase characteristic of the high-frequency signal is corrected based on the phase characteristic of the high-frequency signal generation unit measured by the phase characteristic measurement device.

5. A signal generator comprising:
a high-frequency signal generation unit that generates a high-frequency signal and three-tone signals;
a coupler that branches the signal output from the high-frequency signal generation unit and outputs one of the branched signals as an output signal; and
the phase characteristic measurement device according to claim 2, which, when the high-frequency signal generation unit generates the three-tone signals, receives the other signal branched by the coupler as an input, and measures the phase φ₂″ from the input three-tone signals to measure a phase characteristic of the high-frequency signal generation unit, wherein
when the high-frequency signal generation unit generates the high-frequency signal, a phase characteristic of the high-frequency signal is corrected based on the phase characteristic of the high-frequency signal generation unit measured by the phase characteristic measurement device.

6. A signal generator comprising:
a high-frequency signal generation unit that generates a high-frequency signal and three-tone signals;
a coupler that branches the signal output from the high-frequency signal generation unit and outputs one of the branched signals as an output signal; and
the phase characteristic measurement device according to claim 3, which, when the high-frequency signal generation unit generates the three-tone signals, receives the other signal branched by the coupler as an input, and measures the phase φ₂″ from the input three-tone signals to measure a phase characteristic of the high-frequency signal generation unit, wherein
when the high-frequency signal generation unit generates the high-frequency signal, a phase characteristic of the high-frequency signal is corrected based on the phase characteristic of the high-frequency signal generation unit measured by the phase characteristic measurement device.

7. A signal analyzer comprising:
a reference signal generation unit that generates a reference signal and three-tone signals;
a coupler that branches the signal output from the reference signal generation unit;
the phase characteristic measurement device according to claim 1, which, when the reference signal generation unit generates the three-tone signals, receives one signal branched by the coupler as an input, and measures the phase φ₂″ from the input three-tone signals to measure a phase characteristic of the reference signal generation unit;
a switch that selects either one of the other signal branched by the coupler or an input signal; and
a high-frequency signal analysis unit that analyzes the signal selected by the switch, wherein
a phase characteristic of the high-frequency signal analysis unit is calculated from a phase characteristic of the reference signal measured by the high-frequency signal analysis unit when the reference signal generation unit generates the reference signal and the other signal branched by the coupler is selected by the switch and the phase characteristic of the reference signal generation unit measured by the phase characteristic measurement device, a phase characteristic when the high-frequency signal analysis unit analyzes the input signal is corrected based on the calculated phase characteristic of the high-frequency signal analysis unit, and the input signal with the corrected phase characteristic is analyzed when the input signal is selected by the switch.

8. A signal analyzer comprising:
a reference signal generation unit that generates a reference signal and three-tone signals;
a coupler that branches the signal output from the reference signal generation unit;
the phase characteristic measurement device according to claim 2, which, when the reference signal generation unit generates the three-tone signals, receives one signal branched by the coupler as an input, and measures the phase φ₂″ from the input three-tone signals to measure a phase characteristic of the reference signal generation unit;
a switch that selects either one of the other signal branched by the coupler or an input signal; and
a high-frequency signal analysis unit that analyzes the signal selected by the switch, wherein
a phase characteristic of the high-frequency signal analysis unit is calculated from a phase characteristic of the reference signal measured by the high-frequency signal analysis unit when the reference signal generation unit generates the reference signal and the other signal branched by the coupler is selected by the switch and the phase characteristic of the reference signal generation unit measured by the phase characteristic measurement device, a phase characteristic when the high-frequency signal analysis unit analyzes the input signal is corrected based on the calculated phase characteristic of the high-frequency signal analysis unit, and the input signal with the corrected phase characteristic is analyzed when the input signal is selected by the switch.

9. A signal analyzer comprising:
a reference signal generation unit that generates a reference signal and three-tone signals;
a coupler that branches the signal output from the reference signal generation unit;
the phase characteristic measurement device according to claim 3, which, when the reference signal generation unit generates the three-tone signals, receives one signal branched by the coupler as an input, and measures the phase φ₂″ from the input three-tone signals to measure a phase characteristic of the reference signal generation unit;
a switch that selects either one of the other signal branched by the coupler or an input signal; and
a high-frequency signal analysis unit that analyzes the signal selected by the switch, wherein
a phase characteristic of the high-frequency signal analysis unit is calculated from a phase characteristic of the reference signal measured by the high-frequency signal analysis unit when the reference signal generation unit generates the reference signal and the other signal branched by the coupler is selected by the switch and the phase characteristic of the reference signal generation unit measured by the phase characteristic measurement device, a phase characteristic when the high-frequency signal analysis unit analyzes the input signal is corrected based on the calculated phase characteristic of the high-frequency signal analysis unit, and the input signal with the corrected phase characteristic is analyzed when the input signal is selected by the switch.

10. A phase characteristic measurement method comprising:
a first three-tone signal generation step of generating a first three-tone signal obtained by combining three waves e₁, e₂, e₃ expressed by Expression (8);
a first detection step of detecting the first three-tone signal;
a first bandpass filter step of, from the signal obtained in the first detection step, passing a frequency component of the angular frequency difference Δω and blocking a frequency component twice the angular frequency difference Δω and a direct current component;
a second detection step of detecting the signal passed in the first bandpass filter step;
a first voltage measurement step of measuring a voltage of the signal obtained in the second detection step;
a second three-tone signal generation step of generating a second three-tone signal obtained by combining three waves e′₁, e′₂, e′₃ expressed by Expression (9);
a third detection step of detecting the second three-tone signal;
a second bandpass filter step of, from the signal obtained in the third detection step, passing a frequency component of the angular frequency difference Δω between tones with adjacent frequencies of the second three-tone signal, and blocking a frequency component twice the angular frequency difference Δω and a direct current component;
a fourth detection step of detecting the signal passed in the second bandpass filter step;
a second voltage measurement step of measuring a voltage of the signal obtained in the fourth detection step; and
a phase calculation step of calculating a phase φ₂″ expressed by Expression (10) from a voltage value measured in the first voltage measurement step and a voltage value measured in the second voltage measurement step,
$${e}_{i} = cos ( {ω}_{i} t + {ϕ}_{i} ) , i = 1 , 2 , 3 \qquad ( 8 )$$
(where ωᵢ represents an angular frequency, Φᵢ represents a phase, t represents time, and ω₂−ω₁=ω₃−ω₂=Δω)
$$\begin{matrix}{e}_{1}^{′} = cos ( {ω}_{1} t + {ϕ}_{1} ) \\ {e}_{2}^{′} = sin ( {ω}_{2} t + {ϕ}_{2} ) \\ {e}_{3}^{′} = cos ( {ω}_{3} t + {ϕ}_{3} )\end{matrix} \qquad ( 9 )$$
$$\begin{matrix}{ϕ}_{2}^{″} = \frac{{d}^{2} ϕ}{d {ω}^{2}} {\vert}_{ω = {ω}_{2}} = \frac{{ϕ}_{3} - 2 {ϕ}_{2} + {ϕ}_{1}}{Δ {ω}^{2}} \\ = \frac{2}{Δ {ω}^{2}} {tan}^{- 1} ( \pm \sqrt{\frac{{E}_{beat}^{′}}{{E}_{beat}}} )\end{matrix} \qquad ( 10 )$$
(where E_{beat} represents a value proportional to power of the signal that has passed in the first bandpass filter step, the value being obtained from the voltage value measured in the first voltage measurement step, and E′_{beat} represents a value proportional to power of the signal that has passed in the second bandpass filter step, the value being obtained from the voltage value measured in the second voltage measurement step).

11. A phase characteristic measurement method comprising:
a three-tone signal generation step of generating a three-tone signal obtained by combining three waves e₁, e₂, e₃ expressed by Expression (11);
a first detection step of detecting the three-tone signal;
a bandpass filter step of, from the signal obtained in the first detection step, passing a frequency component of the angular frequency difference Δω and blocking a frequency component twice the angular frequency difference Δω and a direct current component;
a second detection step of detecting the signal passed in the bandpass filter step;
a voltage measurement step of measuring a voltage of the signal obtained in the second detection step; and
a phase calculation step of setting a phase y in Expression (11) to 0, π/2, and π, and calculating a phase φ₂″ expressed by Expression (12) from each voltage value measured by executing the three-tone signal generation step, the first detection step, the bandpass filter step, the second detection step, and the voltage measurement step, respectively,
$$\begin{matrix}{e}_{1} = {a}_{1} cos ( {ω}_{1} t + {ϕ}_{1} ) \\ {e}_{2} ( ψ ) = {a}_{2} cos ( {ω}_{2} t + {ϕ}_{2} - ψ / 2 ) \\ {e}_{3} = {a}_{3} cos ( {ω}_{3} t + {ϕ}_{3} )\end{matrix} \qquad ( 11 )$$
(where a₁, a₂, a₃ represent amplitudes, ω₁, ω₂, ω₃ represent angular frequencies, φ₁, φ₂, φ₃, ψ represent phases, t represents time, ψ=0, π/2, π, and ω₂−ω₁=ω₃−ω₂=Δω)
$${ϕ}_{2}^{″} = \frac{1}{Δ {ω}^{2}} {tan}^{- 1} ( \frac{{E}_{beat} ( 0 ) - 2 {E}_{beat} ( π / 2 ) + {E}_{beat} ( π )}{{E}_{beat} ( 0 ) - {E}_{beat} ( π )} ) \qquad ( 12 )$$
(where E_{beat}(0) represents a value proportional to power of the signal that has passed in the bandpass filter step, the value being obtained from the voltage value measured in the voltage measurement step when ψ=0, E_{beat}(π/2) represents a value proportional to power of the signal that has passed in the bandpass filter step, the value being obtained from the voltage value measured in the voltage measurement step when ψ=π/2, and E_{beat}(π) represents a value proportional to power of the signal that has passed in the bandpass filter step, the value being obtained from the voltage value measured in the voltage measurement step when ψ=π).

12. A phase characteristic measurement method comprising:
a three-tone signal generation step of generating a three-tone signal obtained by combining three waves e₁, e₂, e₃ expressed by Expression (13);
a first detection step of detecting the three-tone signal;
a bandpass filter step of, from the signal obtained in the first detection step, passing a frequency component of the angular frequency difference Δω and blocking a frequency component twice the angular frequency difference Δω and a direct current component;
a second detection step of detecting the signal passed in the bandpass filter step;
a voltage measurement step of measuring a voltage of the signal obtained in the second detection step; and
a phase calculation step of setting a phase y in Expression (13) to 0, π/2, and π, and calculating a phase φ₂″ expressed by Expression (14) from each voltage value measured by executing the three-tone signal generation step, the first detection step, the bandpass filter step, the second detection step, and the voltage measurement step, respectively,
$$\begin{matrix}{e}_{1} = {a}_{1} cos ( {ω}_{1} t + {ϕ}_{1} ) \\ {e}_{2} ( ψ ) = {a}_{2} cos ( {ω}_{2} t + {ϕ}_{2} - ψ / 2 ) \\ {e}_{3} = {a}_{3} cos ( {ω}_{3} t + {ϕ}_{3} )\end{matrix} \qquad ( 13 )$$
(where a₁, a₂, a₃ represent amplitudes, ω₁, ω₂, ω₃ represent angular frequencies, φ₁, φ₂, φ₃, ψ represent phases, t represents time, ψ=0, π/2, π, and ω₂−ω₁=ω₃−ω₂=Δω)
$${ϕ}_{2}^{″} = \frac{1}{Δ {ω}^{2}} a tan 2 ( {E}_{beat} ( 0 ) - 2 {E}_{beat} ( π / 2 ) + {E}_{beat} ( π ) , {E}_{beat} ( 0 ) - {E}_{beat} ( π ) ) \qquad ( 14 )$$
(where E_{beat}(0) represents a value proportional to power of the signal that has passed in the bandpass filter step, the value being obtained from the voltage value measured in the voltage measurement step when ψ=0, E_{beat}(π/2) represents a value proportional to power of the signal that has passed in the bandpass filter step, the value being obtained from the voltage value measured in the voltage measurement step when ψ=π/2, and E_{beat}(π) represents a value proportional to power of the signal that has passed in the bandpass filter step, the value being obtained from the voltage value measured in the voltage measurement step when ψ=π).

13. A signal generation method comprising:
a three-tone signal generation step of generating three-tone signals using a high-frequency signal generation unit;
the phase characteristic measurement method according to claim 10 for measuring a phase characteristic of the high-frequency signal generation unit by measuring the phase φ₂″ from the three-tone signals generated in the three-tone signal generation step; and
a high-frequency signal generation step of generating a high-frequency signal using the high-frequency signal generation unit and outputting the high-frequency signal as an output signal, wherein
a phase characteristic of the high-frequency signal is corrected based on the phase characteristic of the high-frequency signal generation unit measured by the phase characteristic measurement method.

14. A signal generation method comprising:
a three-tone signal generation step of generating three-tone signals using a high-frequency signal generation unit;
the phase characteristic measurement method according to claim 11 for measuring a phase characteristic of the high-frequency signal generation unit by measuring the phase φ₂″ from the three-tone signals generated in the three-tone signal generation step; and
a high-frequency signal generation step of generating a high-frequency signal using the high-frequency signal generation unit and outputting the high-frequency signal as an output signal, wherein
a phase characteristic of the high-frequency signal is corrected based on the phase characteristic of the high-frequency signal generation unit measured by the phase characteristic measurement method.

15. A signal generation method comprising:
a three-tone signal generation step of generating three-tone signals using a high-frequency signal generation unit;
the phase characteristic measurement method according to claim 12 for measuring a phase characteristic of the high-frequency signal generation unit by measuring the phase φ₂″ from the three-tone signals generated in the three-tone signal generation step; and
a high-frequency signal generation step of generating a high-frequency signal using the high-frequency signal generation unit and outputting the high-frequency signal as an output signal, wherein
a phase characteristic of the high-frequency signal is corrected based on the phase characteristic of the high-frequency signal generation unit measured by the phase characteristic measurement method.

16. A signal analysis method comprising:
a three-tone signal generation step of generating three-tone signals using a reference signal generation unit;
the phase characteristic measurement method according to claim 10 for measuring a phase characteristic of the reference signal generation unit by measuring the phase φ₂″ from the three-tone signals generated in the three-tone signal generation step;
a reference signal generation step of generating a reference signal using the reference signal generation unit;
a reference signal analysis step of measuring a phase characteristic of the reference signal using a high-frequency signal analysis unit; and
a high-frequency signal analysis step of analyzing an input signal using the high-frequency signal analysis unit, wherein
a phase characteristic of the high-frequency signal analysis unit is calculated from the phase characteristic of the reference signal generation unit measured by the phase characteristic measurement method and the phase characteristic of the reference signal measured in the reference signal analysis step, a phase characteristic when the input signal is analyzed in the high-frequency signal analysis step is corrected based on the calculated phase characteristic of the high-frequency signal analysis unit, and the input signal with the corrected phase characteristic is analyzed.

17. A signal analysis method comprising:
a three-tone signal generation step of generating three-tone signals using a reference signal generation unit;
the phase characteristic measurement method according to claim 11 for measuring a phase characteristic of the reference signal generation unit by measuring the phase φ₂″ from the three-tone signals generated in the three-tone signal generation step;
a reference signal generation step of generating a reference signal using the reference signal generation unit;
a reference signal analysis step of measuring a phase characteristic of the reference signal using a high-frequency signal analysis unit; and
a high-frequency signal analysis step of analyzing an input signal using the high-frequency signal analysis unit, wherein
a phase characteristic of the high-frequency signal analysis unit is calculated from the phase characteristic of the reference signal generation unit measured by the phase characteristic measurement method and the phase characteristic of the reference signal measured in the reference signal analysis step, a phase characteristic when the input signal is analyzed in the high-frequency signal analysis step is corrected based on the calculated phase characteristic of the high-frequency signal analysis unit, and the input signal with the corrected phase characteristic is analyzed.

18. A signal analysis method comprising:
a three-tone signal generation step of generating three-tone signals using a reference signal generation unit;
the phase characteristic measurement method according to claim 12 for measuring a phase characteristic of the reference signal generation unit by measuring the phase φ₂″ from the three-tone signals generated in the three-tone signal generation step;
a reference signal generation step of generating a reference signal using the reference signal generation unit;
a reference signal analysis step of measuring a phase characteristic of the reference signal using a high-frequency signal analysis unit; and
a high-frequency signal analysis step of analyzing an input signal using the high-frequency signal analysis unit, wherein
a phase characteristic of the high-frequency signal analysis unit is calculated from the phase characteristic of the reference signal generation unit measured by the phase characteristic measurement method and the phase characteristic of the reference signal measured in the reference signal analysis step, a phase characteristic when the input signal is analyzed in the high-frequency signal analysis step is corrected based on the calculated phase characteristic of the high-frequency signal analysis unit, and the input signal with the corrected phase characteristic is analyzed.
